(19) United States
(12) Patent Application Publication
(10) Pub. No.: US 2026/0305084 A1
(43) Pub. Date: Oct. 1, 2026

(54) Display Device, Electronic Device, And Method Of Fabricating The Display Device

(71) Applicant: Samsung Display Co., Ltd., Yongin-si (KR)

(72) Inventor: Chun Gi You, Yongin-si (KR)

(73) Assignee: Samsung Display Co., Ltd., Yongin-si (KR)

(21) Appl. No.: 19/414,535

(22) Filed: Dec. 10, 2025

(30) Foreign Application Priority Data
Mar. 26, 2025 (KR) 10-2025-0038713

(51) Int. Cl. H10K 59/124; H10K 50/19; H10K 59/12; H10K 59/122; H10K 59/131; H10K 59/80; H10K 59/88; H10K 71/16

(52) U.S. Cl. CPC H10K 59/124; H10K 50/19; H10K 59/1201; H10K 59/122; H10K 59/131; H10K 59/80516; H10K 59/879; H10K 59/88; H10K 71/166

(57) ABSTRACT

Provided are a display device capable of preventing a short circuit between pads an electronic device, and a method of fabricating the display device. The display device includes: a substrate having a display area and a non-display area; a connection electrode on the display area of the substrate; a reflective electrode on the connection electrode; a capping layer on the reflective electrode; a first electrode on the capping layer; a pixel defining layer located on the first electrode and defining an emission area exposing the first electrode; a light emitting stack on the first electrode and the pixel defining layer; a second electrode on the light emitting stack; a pad located on a pad portion of the non-display area of the substrate; an insulating layer located on the pad and having a pad contact hole exposing the pad; a residual layer on the insulating layer; and a dummy layer on the residual layer.

### CROSS-REFERENCE TO RELATED APPLICATION

This application claims the benefit of Korean Patent Application No. 10-2025-0038713, filed on Mar. 26, 2025, in the Korean Intellectual Property Office, the disclosure of which is incorporated herein in its entirety by reference.

### TECHNICAL FIELD

The present disclosure relates to a display device, and more particularly, to a display device, specifically a display device capable of preventing short circuit between pads, an electronic device, and a method of fabricating the display device.

### BACKGROUND

An organic light emitting display apparatus includes a display element whose luminance varies according to an electric current, for example, an organic light emitting diode.

### SUMMARY

Aspects of the present disclosure provide a display device capable of preventing short circuit between pads, an electronic device, and a method of fabricating the display device.
According to an aspect of the present disclosure, there is provided a display device including: a substrate having a display area and a non-display area; a connection electrode on the display area of the substrate; a reflective electrode on the connection electrode; a capping layer on the reflective electrode; a first electrode on the capping layer; a pixel defining layer located on the first electrode and defining an emission area exposing the first electrode; a light emitting stack on the first electrode and the pixel defining layer; a second electrode on the light emitting stack; a pad located on a pad portion of the non-display area of the substrate; an insulating layer located on the pad and having a pad contact hole exposing the pad; a residual layer on the insulating layer; and a dummy layer on the residual layer.
According to another aspect of the present disclosure, there is provided an electronic device including a display device that provides a screen. The display device includes: a substrate having a display area and a non-display area; a connection electrode on the display area of the substrate; a reflective electrode on the connection electrode; a capping layer on the reflective electrode; a first electrode on the capping layer; a pixel defining layer located on the first electrode and defining an emission area exposing the first electrode; a light emitting stack on the first electrode and the pixel defining layer; a second electrode on the light emitting stack; a pad located on a pad portion of the non-display area of the substrate; an insulating layer located on the pad and having a pad contact hole exposing the pad; a residual layer on the insulating layer; and a dummy layer on the residual layer.
According to an aspect of the present disclosure, there is provided a method of fabricating a display device, the method comprising: forming a first insulating layer on a semiconductor substrate having a display area and a non-display area; forming a pad connection electrode inside a via hole of the first insulating layer; forming a second insulating layer on the pad connection electrode; forming a first contact hole that exposes the pad connection electrode by penetrating the second insulating layer; forming a pad connected to the pad connection electrode through the first contact hole on the second insulating layer; forming a third insulating layer on the entire surface of the substrate including the pad and the second insulating layer; forming a via hole in the display area by penetrating the third insulating layer; forming a material of a via electrode inside the via hole of the third insulating layer and on the third insulating layer; forming a residual layer of the via electrode on the third insulating layer on the pad in addition to forming the via electrode inside the via hole of the third insulating layer by patterning the material of the via electrode through a chemical mechanical polishing; forming a pad contact hole that exposes a buffer electrode of the pad by penetrating the third insulating layer; forming an intermediate layer on the third insulating layer, the buffer electrode, an inner wall of the pad contact hole and the residual layer; forming an organic layer on the intermediate layer; forming a high refractive index organic layer on the organic layer; forming a first photoresist pattern on the high refractive index organic layer to expose the pad; exposing the intermediate layer on the pad by removing the high refractive index organic layer and the organic layer using the first photoresist pattern as a mask; removing the first photoresist pattern; forming a second photoresist pattern on the intermediate layer and the high refractive index organic layer to expose the pad contact hole; and forming a dummy layer on the third insulating layer and the residual layer by removing the intermediate layer using the second photoresist pattern as a mask.

According to an aspect, since a residual layer of a via electrode is covered by a dummy layer, short circuit between pads may be prevented. For example, the dummy layer may be located between the residual layer and a conductive adhesive member to prevent the residual layer and a conductive member of the conductive adhesive member from contacting each other, and thus, short circuit between the adjacent pads may be prevented.

The effects of the present disclosure are not limited to the above-described effects and other effects which are not described herein will become apparent to those skilled in the art from the following description.

### BRIEF DESCRIPTION OF THE DRAWINGS

These and/or other aspects will become apparent and more readily appreciated from the following description of the aspects, taken in conjunction with the accompanying drawings in which:

FIG. 1 is an exploded perspective view of a display device according to an aspect;

FIG. 2 is a block diagram of the display device according to an aspect;

FIG. 3 is an equivalent circuit diagram of a first subpixel according to an aspect;

FIG. 4 is a layout view of an example of a display panel according to an aspect;

FIGS. 5 and 6 are layout views of aspects of a display area of FIG. 4;

FIG. 7 is a cross-sectional view of an example of the display panel taken along line I1-I1′ of FIG. 5;

FIG. 8 is a detailed cross-sectional view of area A1 of FIG. 7;

FIG. 9 is a detailed cross-sectional view of area A2 of FIG. 8;

FIG. 10 is an enlarged view of the periphery of the first pad of FIG. 4;

FIG. 11 is a plan view of two adjacent first pads of FIG. 10;

FIG. 12 is a cross-sectional view of a display panel taken along line I2-I2′ of FIG. 11;

FIG. 13 is an enlarged view of area A3 of FIG. 12;

FIG. 14 is a diagram for explaining a connection between a display panel and a circuit board of FIG. 12;

FIG. 15 is a cross-sectional view of a display panel including four adjacent first pads;

FIGS. 16, 17, 18, 19, and 20 are process cross-sectional views illustrating a method of fabricating a display device according to an aspect;

FIG. 21 is a block diagram of an electronic device according to an aspect; and

FIGS. 22, 23, and 24 are schematic diagrams of electronic devices according to various aspects.

### DETAILED DESCRIPTION

Aspects of the disclosure will now be described more fully hereinafter with reference to the accompanying drawings, in which preferred aspects of the disclosure are shown. Aspects of the present disclosure may, however, be embodied in different forms and should not be construed as limited to the aspects set forth herein. Rather, these aspects are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more aspects. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various aspects of the present disclosure may be combined partially or totally. As will be clearly appreciated by those skilled in the art, technically various interactions and operations are possible. Various aspects can be practiced individually or in combination.

Hereinafter, specific exemplary aspects will be described with reference to the accompanying drawings.

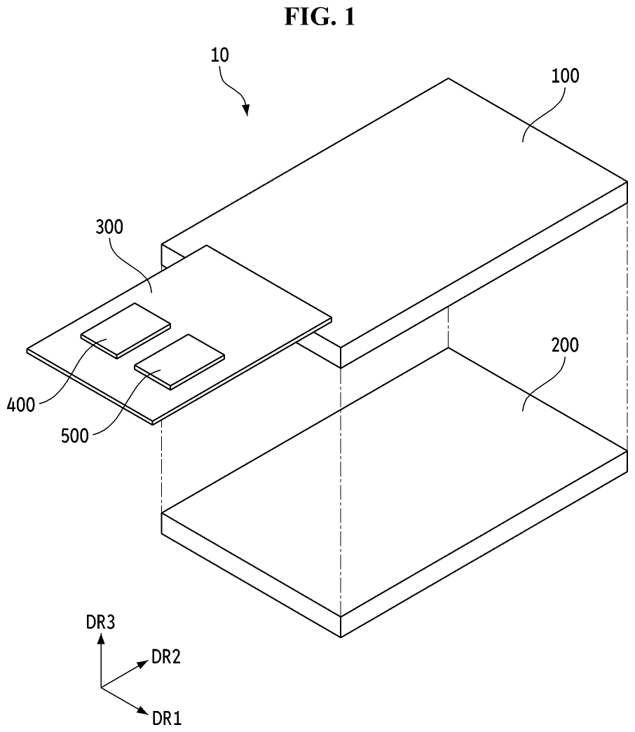

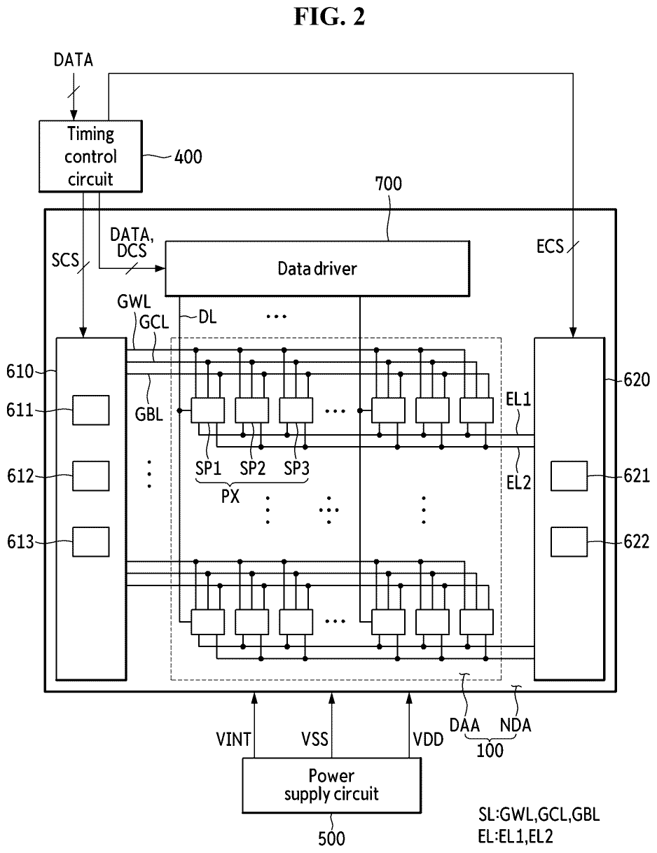

FIG. 1 is an exploded perspective view of a display device according to an aspect. FIG. 2 is a block diagram of the display device according to the aspect.

Referring to FIGS. 1 and 2, a display device 10 according to the aspect is a device for displaying moving images or still images. The display device 10 according to the aspect may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to the aspect may be applied as a display unit of a television, a notebook computer, a monitor, a billboard, or an Internet of things (IoT) device. Alternatively, the display device 10 according to the aspect may be applied to smart watches, watch phones, and head mounted displays for implementing virtual reality and augmented reality.

The display device 10 according to the aspect may include a display panel 100, a heat dissipation layer 200, a circuit board 300, a timing control circuit 400, and a power supply circuit 500.

The display panel 100 may have a planar shape similar to a quadrangle. For example, the display panel 100 may have a planar shape similar to a quadrangle having short sides in a first direction DR1 and long sides in a second direction DR2 intersecting the first direction DR1. In the display panel 100, each corner where a short side extending in the first direction DR1 meets a long side extending in the second direction DR2 may be rounded with a predetermined curvature or may be right-angled. The planar shape of the display panel 100 is not limited to a quadrangular shape and may also be similar to other polygonal shapes, a circular shape, or an oval shape. The planar shape of the display device 10 may follow the planar shape of the display panel 100, but aspects of the present specification are not limited thereto.

The display panel 100 includes a plurality of pixels PX, a plurality of scan lines SL, a plurality of emission control lines EL, a plurality of data lines DL, a scan driver 610, an emission driver 620, and a data driver 700. As illustrated in FIG. 2, the display panel 100 may be divided into a display area DAA displaying an image and a non-display area NDA not displaying an image.

The pixels PX may be arranged in the display area DAA. The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL include a plurality of write scan lines GWL, a plurality of control scan lines GCL, and a plurality of bias scan lines GBL. The emission control lines EL include a plurality of first emission control lines EL1 and a plurality of second emission control lines EL2.

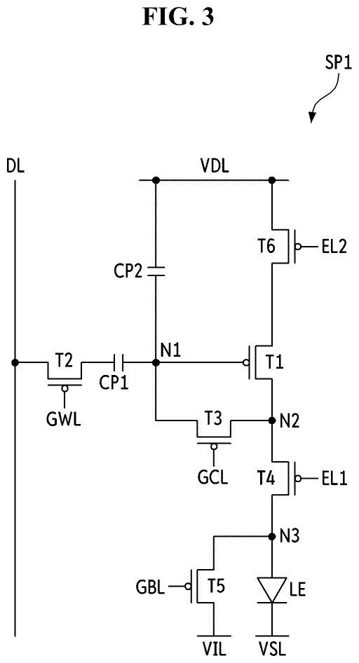

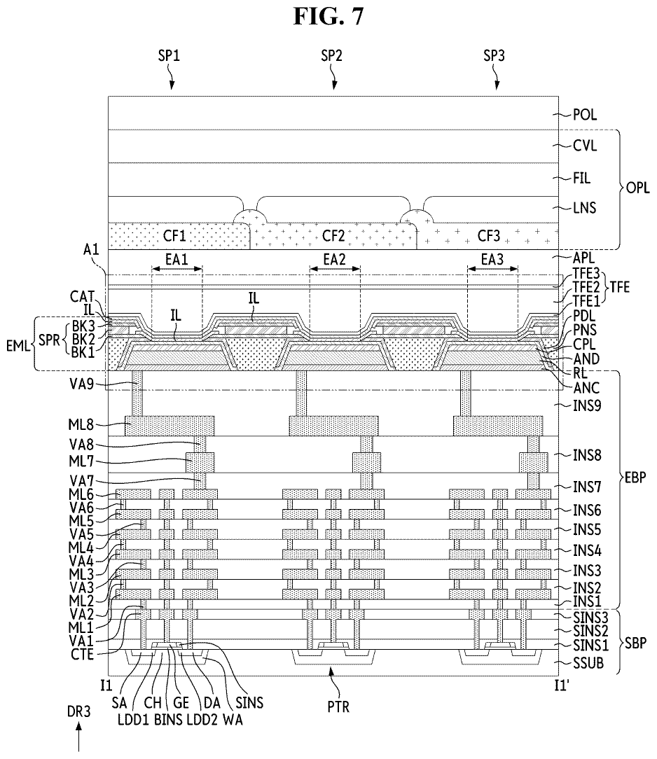

Each of the pixels PX includes a plurality of subpixels SP1 through SP3. Each of the subpixels SP1 through SP3 includes a plurality of pixel transistors as illustrated in FIG. 3. The pixel transistors may be formed through a semiconductor process and may be located in a semiconductor substrate SSUB (see FIG. 7). For example, a plurality of pixel transistors of the data driver 700 may be formed as complementary metal oxide semiconductor (CMOS) transistors, but aspects of the present specification are not limited thereto.

Each of the subpixels SP1 through SP3 may be connected to any one of the write scan lines GWL, any one of the control scan lines GCL, any one of the bias scan lines GBL, any one of the first emission control lines EL1, any one of the second emission control lines EL2, and any one of the data lines DL. Each of the subpixels SP1 through SP3 may receive a data voltage of a data line DL according to a write scan signal of a write scan line GWL and emit light from a light emitting element according to the data voltage.

The scan driver 610, the emission driver 620, and the data driver 700 may be located in the non-display area NDA.

The scan driver 610 includes a plurality of scan transistors, and the emission driver 620 includes a plurality of emission transistors. The scan transistors and the emission transistors may be formed through a semiconductor process and may be formed in the semiconductor substrate SSUB (see FIG. 7). For example, the scan transistors and the emission transistors may be formed as CMOS transistors, but aspects of the present specification are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driving unit 621 and a second emission control driving unit 622. Each of the first emission control driving unit 621 and the second emission control driving unit 622 may receive an emission timing control signal ECS from the timing control circuit 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 includes a plurality of data transistors. The data transistors may be formed through a semiconductor process and may be formed in the semiconductor substrate SSUB (see FIG. 7). For example, the data transistors may be formed as CMOS transistors, but aspects of the present specification are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, subpixels SP1 through SP3 may be selected by a write scan signal of the scan driver 610, and the data voltages may be supplied to the selected subpixels SP1 through SP3.

The heat dissipation layer 200 may overlap the display panel 100 in a third direction DR3 which is a thickness direction of the display panel 100. The heat dissipation layer 200 may be located on a surface, e.g., a back surface of the display panel 100. The heat dissipation layer 200 dissipates heat generated from the display panel 100. The heat dissipation layer 200 may include a metal layer having high thermal conductivity, such as graphite, silver (Ag), copper (Cu), or aluminum (Al).

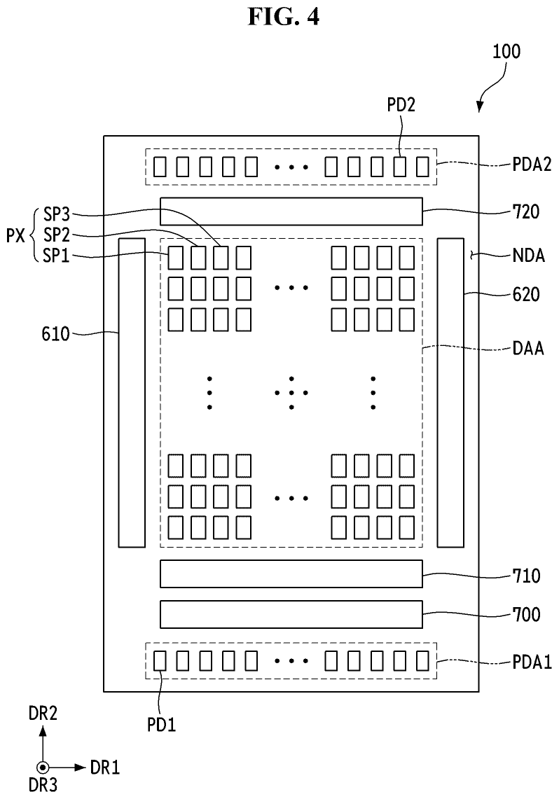

The circuit board 300 may be electrically connected to a plurality of first pads PD1 (see FIG. 4) in a first pad portion PDA1 (see FIG. 4) of the display panel 100 by using a conductive adhesive member such as an anisotropic conductive film. The circuit board 300 may be a flexible printed circuit board or a flexible film. Although the circuit board 300 is unfolded in FIG. 1, it may also be bent. In this case, one end of the circuit board 300 may be placed on the back surface of the display panel 100 and/or a back surface of the heat dissipation layer 200. The other end of the circuit board 300 may be connected to the first pads PD1 (see FIG. 4) of the first pad portion PDA1 (see FIG. 4) of the display panel 100 by using a conductive adhesive member. The one end of the circuit board 300 may be an end opposite the other end of the circuit board 300.

The timing control circuit 400 may receive digital video data and timing signals from the outside. The timing control circuit 400 may generate the scan timing control signal SCS, the emission timing control signal ECS, and the data timing control signal DCS for controlling the display panel 100 according to the timing signals. The timing control circuit 400 may output the scan timing control signal SCS to the scan driver 610 and the emission timing control signal ECS to the emission driver 620. The timing control circuit 400 may output the digital video data and the data timing control signal DCS to the data driver 700.

The power supply circuit 500 may generate a plurality of panel driving voltages according to a power supply voltage received from the outside. For example, the power supply circuit 500 may generate a first driving voltage VSS, a second driving voltage VDD, and a third driving voltage VINT to supply them to the display panel 100. The first driving voltage VSS, the second driving voltage VDD, and the third driving voltage VINT will be described later with reference to FIG. 3.

Each of the timing control circuit 400 and the power supply circuit 500 may be formed as an integrated circuit (IC) and attached to a surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

Alternatively, the timing control circuit 400 and the power supply circuit 500 may be located in the non-display area NDA of the display panel 100, like the scan driver 610, the emission driver 620, and the data driver 700. In this case, the timing control circuit 400 may include a plurality of timing transistors, and the power supply circuit 500 may include a plurality of power transistors. The timing transistors and the power transistors may be formed through a semiconductor process and may be formed in the semiconductor substrate SSUB (see FIG. 7). For example, the timing transistors and the power transistors may be formed as CMOS transistors, but aspects of the present specification are not limited thereto. Each of the timing control circuit 400 and the power supply circuit 500 may be located between the data driver 700 and the first pad portion PDA1 (see FIG. 4).

FIG. 3 is an equivalent circuit diagram of a first subpixel according to an aspect.

Referring to FIG. 3, the first subpixel SP1 may be connected to a write scan line GWL, a control scan line GCL, a bias scan line GBL, a first emission control line EL1, a second emission control line EL2, and a data line DL. In addition, the first subpixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low-potential voltage line, the second driving voltage line VDL may be a high-potential voltage line, and the third driving voltage line VIL may be an initialization voltage line. Here, the first driving voltage VSS may be lower than the third driving voltage VINT. The second driving voltage VDD may be higher than the third driving voltage VINT.

The first subpixel SP1 includes a plurality of transistors T1 through T6, a light emitting element LE, a first capacitor CP1, and a second capacitor CP2.

The light emitting element LE emits light according to a driving current flowing through a channel of a first transistor T1. The amount of light emitted from the light emitting element LE may be proportional to the driving current Ids. The light emitting element LE may be located between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer located between the first electrode and the second electrode. However, aspects of the present specification are not limited thereto. For example, the light emitting element LE may be an inorganic light emitting element including a first electrode, a second electrode, and an inorganic semiconductor located between the first electrode and the second electrode. In this case, the light emitting element LE may be a micro light emitting diode.

The first transistor T1 may be a driving transistor that controls a source-drain current Ids (hereinafter, referred to as a “driving current”) flowing between a source electrode and a drain electrode according to a voltage applied to a gate electrode. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL and connects one electrode of the first capacitor CP1 to the data line DL. Accordingly, a data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be located between the first node N1 and the second node N2. The third transistor T3 is turned on by a write control signal of the write control line GCL and connects the first node N1 to the second node N2. Accordingly, when the gate electrode and source electrode of the first transistor T1 are connected, the first transistor T1 may operate as a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 and connects the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be located between the third node N3 and the third driving voltage line VIL. The fifth transistor T5 is turned on by a bias scan signal of the bias scan line GBL and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by a second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, aspects of the present specification are not limited thereto. Each of the first through sixth transistors T1 through T6 may also be an N-type MOSFET. Alternatively, some of the first through sixth transistors T1 through T6 may be P-type MOSFETs, and the other transistors may be N-type MOSFETs.

In FIG. 3, the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and the number of capacitors in the first subpixel SP1 are not limited to those illustrated in FIG. 3.

In addition, an equivalent circuit diagram of a second subpixel SP2 and an equivalent circuit diagram of a third subpixel SP3 may be substantially the same as the equivalent circuit diagram of the first subpixel SP1 described with reference to FIG. 3. Therefore, the equivalent circuit diagram of the second subpixel SP2 and the equivalent circuit diagram of the third subpixel SP3 will not be described in the present specification.

FIG. 4 is a layout view of an example of a display panel according to an aspect.

Referring to FIG. 4, a display area DAA of the display panel 100 according to the aspect includes a plurality of pixels PX arranged in a matrix form. A non-display area NDA of the display panel 100 according to the aspect includes a scan driver 610, an emission driver 620, a data driver 700, a first distribution circuit 710, a second distribution circuit 720, a first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on a left side of the display area DAA, and the emission driver 620 may be located on a right side of the display area DAA. However, aspects of the present specification are not limited thereto, and the scan driver 610 and the emission driver 620 may also be located on both the first and second sides of the display area DAA.

The first pad portion PDA1 may include a plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2. That is, the first pad portion PDA1 may be located closer to an edge of the display panel 100 than the data driver 700.

The second pad portion PDA2 may include a plurality of second pads PD2 corresponding to inspection pads for inspecting whether the display panel 100 operates normally. The second pads PD2 may be connected to a jig or a probe pin during an inspection process or may be connected to a circuit board for inspection. The circuit board for inspection may be a rigid printed circuit board or a flexible printed circuit board.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2. That is, the second pad portion PDA2 may be located closer to an edge of the display panel 100 than the second distribution circuit 720.

The first distribution circuit 710 distributes data voltages received through the first pad portion PDA1 to a plurality of data lines DL. For example, the first distribution circuit 710 may distribute data voltages received through one first pad PD1 of the first pad portion PDA1 to P (P is a positive integer of 2 or more) data lines DL. Therefore, the number of first pads PD1 can be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on a lower side of the display area DAA.

The second distribution circuit 720 distributes signals received through the second pad portion PDA2 to the scan driver 610, the emission driver 620, and the data lines DL. The second pad portion PDA2 and the second distribution circuit 720 may be elements for inspecting the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on an upper side of the display area DAA.

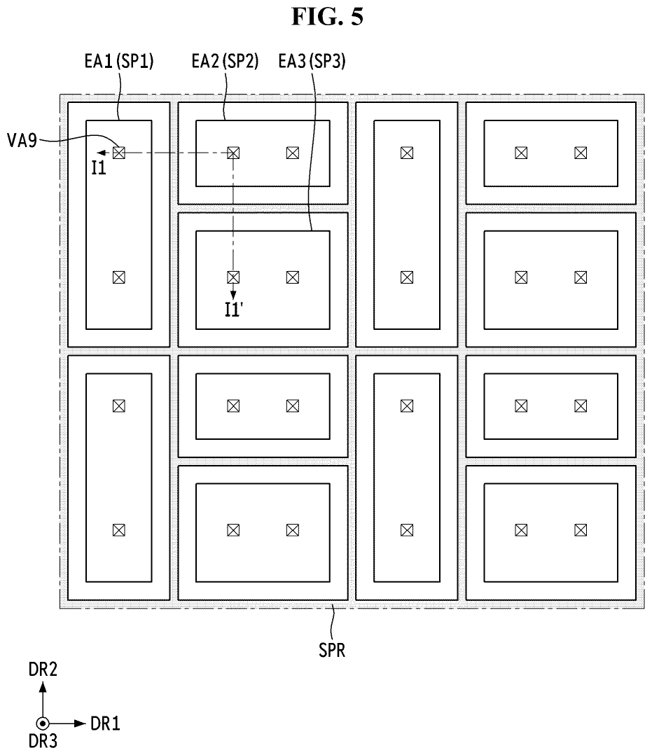

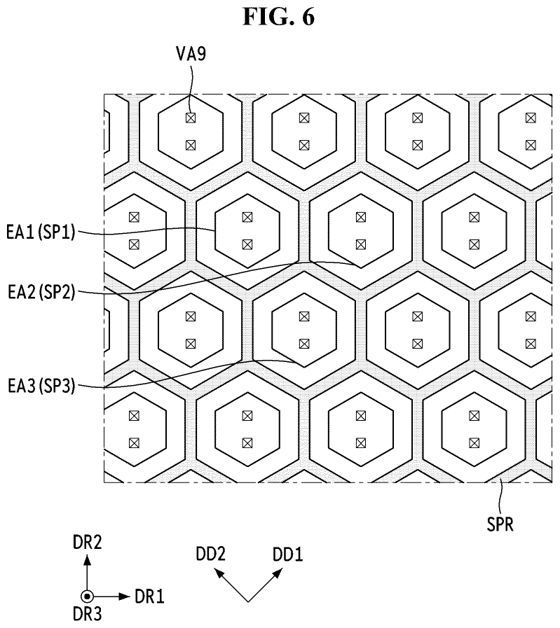

FIGS. 5 and 6 are layout views of aspects of a display area of FIG. 4.

Referring to FIGS. 5 and 6, each of a plurality of pixels PX includes a first emission area EA1 which is an emission area of a first subpixel SP1, a second emission area EA2 which is an emission area of a second subpixel SP2, and a third emission area EA3 which is an emission area of a third subpixel SP3.

Each of the first emission area EA1, the second emission area EA2, and the third emission area EA3 may have a polygonal, circular, oval, or irregular planar shape.

A maximum length of the first emission area EA1 in the first direction DR1 may be smaller than a maximum length of the second emission area EA2 in the first direction DR1 and a maximum length of the third emission area EA3 in the first direction DR1. The maximum length of the second emission area EA2 in the first direction DR1 may be substantially equal to the maximum length of the third emission area EA3 in the first direction DR1.

A maximum length of the first emission area EA1 in the second direction DR2 may be greater than a maximum length of the second emission area EA2 in the second direction DR2 and a maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have a quadrangular shape as illustrated in FIG. 5 or a hexagonal shape as illustrated in FIG. 6. However, aspects of the present specification are not limited thereto. The first emission area EA1, the second emission area EA2, and the third emission area EA3 may also have a polygonal planar shape other than a hexagonal shape or an oval or irregular planar shape.

As illustrated in FIG. 5, in each of the pixels PX, the first emission area EA1 and the second emission area EA2 may neighbor each other in the first direction DR1. In addition, the first emission area EA1 and the third emission area EA3 may neighbor each other in the first direction DR1. In addition, the second emission area EA2 and the third emission area EA3 may neighbor each other in the second direction DR2. The area of the first emission area EA1, the area of the second emission area EA2, and the area of the third emission area EA3 may be different.

Alternatively, as illustrated in FIG. 6, the first emission area EA1 and the second emission area EA2 may neighbor each other in the first direction DR1. However, the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2 and a direction inclined at 45 degrees with respect to the first direction DR1 and the second direction DR2. The second diagonal direction DD2 may be a direction orthogonal to the first diagonal direction DD1.

The first subpixel SP1 may output first light that has passed through a first color filter CF1 (see FIG. 7) among light emitted from the first emission area EA1, the second subpixel SP2 may output second light that has passed through a second color filter CF2 (see FIG. 7) among light emitted from the second emission area EA2, and the third subpixel SP3 may output third light that has passed through a third color filter CF3 (see FIG. 7) among light emitted from the third emission area EA3.

The first light, the second light, and the third light may be light of different wavelength bands. For example, any one of the first light, the second light and the third light may be light in a blue wavelength band, another may be light in a green wavelength band, and the other may be light in a red wavelength band. Here, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Although each of the pixels PX includes three emission areas EA1 through EA3 in FIGS. 5 and 6, aspects of the present specification are not limited thereto. That is, each of the pixels PX may also include four emission areas.

In addition, the arrangement of the emission areas of the pixels PX is not limited to those illustrated in FIGS. 5 and 6. For example, the emission areas of the pixels PX may also be arranged in a stripe structure in which emission areas are arranged in the first direction DR1, in a PenTile® structure in which emission areas are arranged in a diamond shape, or in a hexagonal structure in which emission areas having a hexagonal planar shape are arranged as illustrated in FIG. 6.

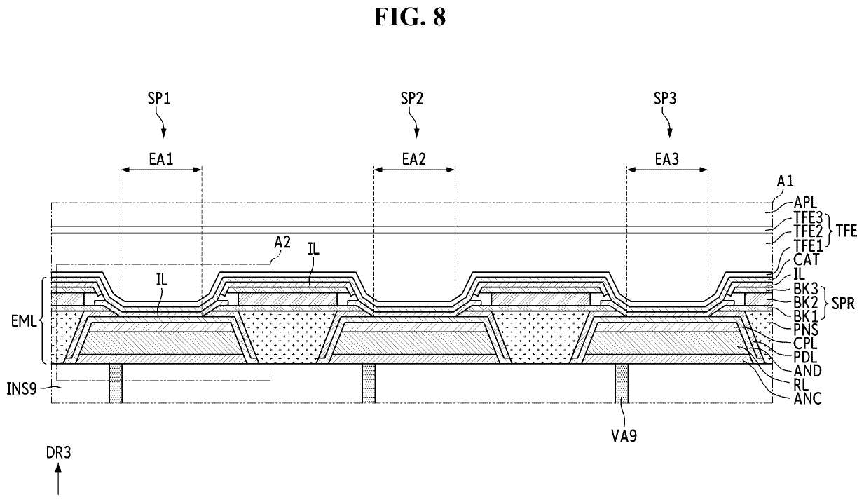

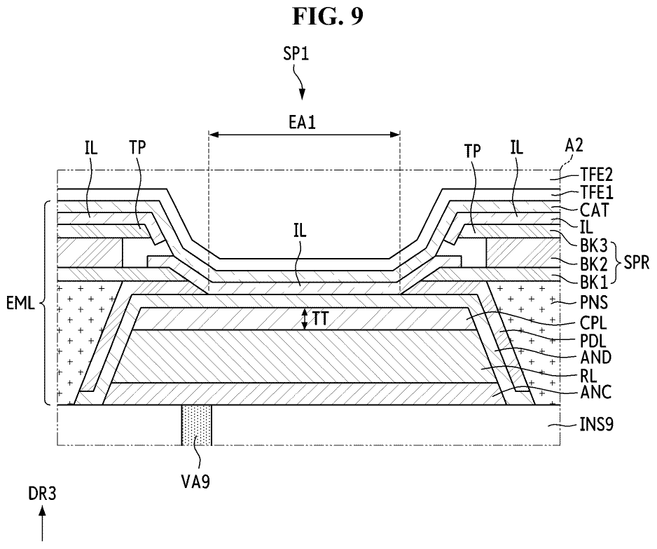

FIG. 7 is a cross-sectional view of an example of the display panel taken along line I1-I1′ of FIG. 5. FIG. 8 is a detailed cross-sectional view of area A1 of FIG. 7. FIG. 9 is a detailed cross-sectional view of area A2 of FIG. 8.

Referring to FIGS. 7 through 9, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR. The pixel transistors PTR may be the first through sixth transistors T1 through T6 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well regions WA may be located in an upper surface of the semiconductor substrate SSUB. The well regions WA may be areas doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities. The semiconductor substrate SSUB may include a display area DAA and a non-display area NDA.

Each of the well regions WA includes a source region SA corresponding to a source electrode of a pixel transistor PTR, a drain region DA corresponding to a drain electrode of the pixel transistor PTR, and a channel region CH located between the source region SA and the drain region DA.

A bottom insulating layer BINS may be located between a gate electrode GE and each well region WA. A side insulating layer SINS may be located on side surfaces of the gate electrode GE. The side insulating layer SINS may be located on the bottom insulating layer BINS.

The source region SA and the drain region DA may be an area doped with the first-type impurities. The gate electrode GE of each pixel transistor PTR may overlap a well region WA in the third direction DR3 which is a thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the well regions WA further includes a first low-concentration impurity region LDD1 located between the channel region CH and the source region SA and a second low-concentration impurity region LDD2 located between the channel region CH and the drain region DA. The first low-concentration impurity region LDD1 may be an area having a lower impurity concentration than the source region SA due to the bottom insulating layer BINS. The second low-concentration impurity region LDD2 may be an area having a lower impurity concentration than the drain region DA due to the bottom insulating layer BINS. A distance between the source region SA and the drain region DA may be increased by the first low-concentration impurity region LDD1 and the second low-concentration impurity region LDD2. Accordingly, a length of the channel region CH of each pixel transistor PTR may increase, thereby preventing punch-through and hot carrier phenomena caused by a short channel.

A first semiconductor insulating layer SINS1 may be located on the semiconductor substrate SSUB. The first semiconductor insulating layer SINS1 may include a silicon carbon nitride (SiCN) or silicon oxide (SiOₓ)-based inorganic layer, but aspects of the present specification are not limited thereto.

A second semiconductor insulating layer SINS2 may be located on the first semiconductor insulating layer SINS1. The second semiconductor insulating layer SINS2 may include a silicon oxide (SiOₓ)-based inorganic layer, but aspects of the present specification are not limited thereto.

The contact terminals CTE may be located on the second semiconductor insulating layer SINS2. Each of the contact terminals CTE may be connected to any one of the gate electrode GE, the source region SA, and the drain region DA of a pixel transistor PTR through a hole penetrating the first semiconductor insulating layer SINS1 and the second semiconductor insulating layer SINS2. The contact terminals CTE may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same.

A third semiconductor insulating layer SINS3 may be located on side surfaces of each of the contact terminals CTE. An upper surface of each of the contact terminals CTE may be exposed without being covered by the third semiconductor insulating layer SINS3. The third semiconductor insulating layer SINS3 may include a silicon oxide (SiOₓ)-based inorganic layer, but aspects of the present specification are not limited thereto.

The semiconductor substrate SSUB can be replaced with a glass substrate or a polymer resin substrate such as polyimide. In this case, thin-film transistors may be located on the glass substrate or the polymer resin substrate. The glass substrate may be a rigid substrate that is not bent, and the polymer resin substrate may be a flexible substrate that can be bent or curved.

The light emitting element backplane EBP includes a plurality of conductive layers ML1 through ML8, a plurality of via electrodes VA1 through VA9, and a plurality of insulating layers INS1 through INS9. In addition, the light emitting element backplane EBP includes a plurality of insulating layers INS1 through INS9 located between first through eighth conductive layers ML1 through ML8.

The first through eighth conductive layers ML1 through ML8 implement the circuit of the first subpixel SP1 illustrated in FIG. 3 by connecting the contact terminals CTE exposed in the semiconductor backplane SBP. For example, the first through sixth transistors T1 through T6 are simply formed in the semiconductor backplane SBP, and the connection of the first through sixth transistors T1 through T6 and the first and second capacitors CP1 and CP2 are achieved through the first through eighth conductive layers ML1 through ML8. In addition, the connection between a drain region corresponding to the drain electrode of the fourth transistor T4, a source region corresponding to the source electrode of the fifth transistor T5, and the first electrode AND of the light emitting element LE is achieved through the first through eighth conductive layers ML1 through ML8.

A first insulating layer INS1 may be located on the semiconductor backplane SBP. First via electrodes VA1 may penetrate the first insulating layer INS1 and may be respectively connected to the contact terminals CTE exposed in the semiconductor backplane SBP. The first conductive layers ML1 may be located on the first insulating layer INS1 and may be connected to the first via electrodes VA1, respectively.

A second insulating layer INS2 may be located on the first insulating layer INS1 and the first conductive layers ML1. Second via electrodes VA2 may penetrate the second insulating layer INS2 and may be connected to the exposed first conductive layers ML1, respectively. The second conductive layers ML2 may be located on the second insulating layer INS2 and may be connected to the second via electrodes VA2, respectively.

A third insulating layer INS3 may be located on the second insulating layer INS2 and the second conductive layers ML2. Third via electrodes VA3 may penetrate the third insulating layer INS3 and may be connected to the exposed second conductive layers ML2, respectively. The third conductive layers ML3 may be located on the third insulating layer INS3 and may be connected to the third via electrodes VA3, respectively.

A fourth insulating layer INS4 may be located on the third insulating layer INS3 and the third conductive layers ML3. Fourth via electrodes VA4 may penetrate the fourth insulating layer INS4 and may be connected to the exposed third conductive layers ML3, respectively. The fourth conductive layers ML4 may be located on the fourth insulating layer INS4 and may be connected to the fourth via electrodes VA4, respectively.

A fifth insulating layer INS5 may be located on the fourth insulating layer INS4 and the fourth conductive layers ML4. Fifth via electrodes VA5 may penetrate the fifth insulating layer INS5 and may be connected to the exposed fourth conductive layers ML4, respectively. The fifth conductive layers ML5 may be located on the fifth insulating layer INS5 and may be connected to the fifth via electrodes VA5, respectively.

A sixth insulating layer INS6 may be located on the fifth insulating layer INS5 and the fifth conductive layers ML5. Sixth via electrodes VA6 may penetrate the sixth insulating layer INS6 and may be connected to the exposed fifth conductive layers ML5, respectively. The sixth conductive layers ML6 may be located on the sixth insulating layer INS6 and may be connected to the sixth via electrodes VA6, respectively.

A seventh insulating layer INS7 may be located on the sixth insulating layer INS6 and the sixth conductive layers ML6. Each of seventh via electrodes VA7 may penetrate the seventh insulating layer INS7 and may be connected to an exposed sixth conductive layer ML6. The seventh conductive layers ML7 may be located on the seventh insulating layer INS7 and may be connected to the seventh via electrodes VA7, respectively.

An eighth insulating layer INS8 may be located on the seventh insulating layer INS7 and the seventh conductive layers ML7. Eighth via electrodes VA8 may penetrate the eighth insulating layer INS8 and may be connected to the exposed seventh conductive layers ML7, respectively. The eighth conductive layers ML8 may be located on the eighth insulating layer INS8 and may be connected to the eighth via electrodes VA8, respectively.

The first through eighth conductive layers ML1 through ML8 and the first through eighth via electrodes VA1 through VA8 may include substantially the same material. The first through eighth conductive layers ML1 through ML8 and the first through eighth via electrodes VA1 through VA8 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. The first through eighth via electrodes VA1 through VA8 may include substantially the same material. The first through eighth insulating layers INS1 through INS8 may include a silicon oxide (SiOₓ)-based inorganic layer, but aspects of the present specification are not limited thereto.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than a thickness of the first via electrodes VA1, a thickness of the second via electrodes VA2, a thickness of the third via electrodes VA3, a thickness of the fourth via electrodes VA4, a thickness of the fifth via electrodes VA5, and a thickness of the sixth via electrodes VA6. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be substantially the same. For example, the thickness of the first conductive layer ML1 may be approximately 1,360 Å; the thickness of each of the second conductive layer ML2, the third conductive layer ML3, the fourth conductive layer ML4, the fifth conductive layer ML5, and the sixth conductive layer ML6 may be approximately 1,440 Å; and the thickness of each of the first via electrode VA1, the second via electrode VA2, the third via electrode VA3, the fourth via electrode VA4, the fifth via electrode VA5, and the sixth via electrode VA6 may be approximately 1,150 Å.

A thickness of the seventh conductive layer ML7 and a thickness of the eighth conductive layer ML8 may each be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may each be greater than a thickness of the seventh via electrode VA7 and a thickness of the eighth via electrode VA8. The thickness of the seventh via electrode VA7 and the thickness of the eighth via electrode VA8 may each be greater than the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6. The thickness of the seventh conductive layer ML7 and the thickness of the eighth conductive layer ML8 may be substantially the same. For example, the thickness of the seventh conductive layer ML7 and the thickness of the eighth conductive layer ML8 may each be about 9,000 Å. The thickness of the seventh via electrode VA7 and the thickness of the eighth via electrode VA8 may each be about 6,000 Å.

A ninth insulating layer INS9 may be located on the eighth insulating layer INS8 and the eighth conductive layer ML8. The ninth insulating layer INS9 may include a silicon oxide (SiOₓ)-based inorganic layer, but aspects of the present specification are not limited thereto.

Ninth via electrodes VA9 may penetrate the ninth insulating layer INS9 and may be connected to the exposed eighth conductive layers ML8, respectively. The ninth via electrodes VA9 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. A thickness of the ninth via electrode VA9 may be about 16,500 Å.

The display element layer EML may be located on the light emitting element backplane EBP. The display element layer EML may include a plurality of connection electrodes ANC, a plurality of reflective electrodes RL, a planarization layer PNS, a plurality of pixel defining layers PDL, a plurality of first electrodes AND, a light emitting stack IL, a second electrode CAT, and a separator SPR.

In addition, the display element layer EML may include a first emission area EA1, a second emission area EA2, and a third emission area EA3. Each of the first emission area EA1, the second emission area EA2, and the third emission area EA3 may be an area where a first electrode AND, the light emitting stack IL, and the second electrode CAT are sequentially stacked. Each of the first emission area EA1, the second emission area EA2, and the third emission area EA3 may be an area where a light emitting element LE including the first electrode AND, the light emitting stack IL, and the second electrode CAT is located. Each of the first emission area EA1, the second emission area EA2, and the third emission area EA3 may be defined by the pixel defining layer PDL.

The connection electrodes ANC may be located on the ninth insulating layer INS9. For example, the connection electrodes ANC may be located on the ninth insulating layer INS9 such that they are connected to the ninth via electrodes VA9, respectively. The connection electrodes ANC may include titanium nitride (TiN) or a transparent conductive oxide. For example, the transparent conductive oxide may be indium tin oxide (ITO) or indium zinc oxide (IZO), but aspects of the present specification are not limited thereto.

The reflective electrodes RL may be located on the connection electrodes ANC, respectively. For example, the reflective electrodes RL may be located between the connection electrodes ANC and capping layers CPL, respectively. Each of the reflective electrodes RL may include any one of copper (Cu), aluminum (Al), silver (Ag), tungsten (W), molybdenum (Mo), chromium (Cr), gold (Au), titanium (Ti), nickel (Ni) and neodymium (Nd) or may include an alloy including any one of the same. For example, each of the reflective electrodes RL may include aluminum (Al) or silver (Ag).

The capping layers CPL may be located on the reflective electrodes RL, respectively. For example, the capping layer CPL may be located on the upper surface of the reflective electrode RL. A thickness TT of the capping layer CPL in different sub-pixels may be the same. For example, the thickness of the capping layer CPL overlapping the first emission area EA1 of the first subpixel SP1, a thickness of the capping layer CPL overlapping the second emission area EA2 of the second subpixel SP2, and a thickness of the capping layer CPL overlapping the third emission area EA3 of the third subpixel SP3 may be the same as each other. The capping layer CPL may be formed of a silicon oxide (SiOx)-based inorganic layer, but aspects of the present specification are not limited thereto.

Each of light emitting elements LE may include a first electrode AND, the light emitting stack IL, and the second electrode CAT.

The first electrode AND may be located on the capping layer CPL. For example, the first electrode AND may be located on an upper surface of the capping layer CPL, side surfaces of capping layer CPL, side surfaces of a reflective electrode RL, side surfaces of the connection electrode ANC, and an upper surface of the ninth insulating layer INS9. The first electrode AND may contact (or directly contact) the upper surface of the capping layer CPL, the side surfaces of the capping layer CPL, the side surfaces of the reflective electrode RL, the side surfaces of the connection electrode ANC, and the upper surface of the ninth insulating layer INS9. Since side surfaces of the first electrode AND and the side surfaces of the connection electrode ANC contact each other, the first electrode AND and the connection electrode ANC may be electrically connected to each other.

A thickness of the first electrode AND on the side surfaces of the capping layer CPL may be different from a thickness of the first electrode AND on the upper surface of capping layer CPL. For example, the thickness of the first electrode AND on the side surfaces of the capping layer CPL may be smaller than the thickness of the first electrode AND on the upper surface of the capping layer CPL. Specifically, the thickness of the first electrode AND overlapping the side surfaces of the capping layer CPL may be smaller than the thickness of the first electrode AND overlapping the upper surface of the capping layer CPL.

The first electrode AND of each of the light emitting elements LE may be connected to the drain region DA or the source region SA of a pixel transistor PTR through the connection electrode ANC, the first through ninth via electrodes VA1 through VA9, the first through eighth conductive layers ML1 through ML8, and a contact terminal CTE.

The first electrode AND of each of the light emitting elements LE may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the first electrode AND of each of the light emitting elements LE may be titanium nitride (TiN).

The pixel defining layers PDL may define the first through third emission areas EA1 through EA3. The pixel defining layer PDL may be located on a partial area of the first electrode AND of each of the light emitting elements LE. The pixel defining layer PDL may cover edges of the first electrode AND of each of the light emitting elements LE. The pixel defining layer PDL may contact (or directly contact) the first electrode AND. The pixel defining layer PDL may be located on the first electrode AND. For example, the pixel defining layer PDL may be located on the upper surface of the first electrode AND and the side surface of the first electrode AND. The pixel defining layer PDL may include a material including a silicon nitride (SiNx). On the other hand, as the pixel defining layer PDL is formed of a different material from the planarization layer PNS, which will be described later, the pixel defining layer PDL may function as an etch stop film that defines the thickness (or height) of the planarization layer PNS when the planarization layer PNS is removed by chemical mechanical polishing (CMP).

The first emission area EA1 may be defined as an area in the first subpixel SP1 where a first electrode AND, the light emitting stack IL, and the second electrode CAT are sequentially stacked to emit light. The second emission area EA2 may be defined as an area in the second subpixel SP2 where a first electrode AND, the light emitting stack IL, and the second electrode CAT are sequentially stacked to emit light. The third emission area EA3 may be defined as an area in the third subpixel SP3 where a first electrode AND, the light emitting stack IL, and the second electrode CAT are sequentially stacked to emit light.

The planarization layer PNS may be located between the first electrodes AND of the subpixels in order to remove steps between the subpixels SP1, SP2, and SP3. For example, the planarization layer PNS may be located between the pixel defining layers PDL. The planarization layer PNS may include a material including a silicon oxide (SiOx).

The separator SPR may be located on the pixel defining layer PDL and the planarization layer PNS. In plan view, as illustrated in FIGS. 5 and 6, each separator SPR may be shaped like a closed curve surrounding each of the emission areas EA1 through EA3. Each separator SPR may be located on the pixel defining layer PDL and the planarization layer PNS to surround each of the emission areas EA1 through EA3. The separator SPR may be a structure to cut the light emitting stack IL. To this end, according to an aspect, the separator SPR may include a first bank BK1, a second bank BK2, and a third bank BK3 having different areas.

The first bank BK1 may be located on the pixel defining layer PDL and the planarization layer PNS. The first bank BK1 may be formed of the same material as the planarization layer PNS. For example, the first bank BK1 may include a material including silicon oxide (SiOₓ). In this case, the first bank BK1 and the planarization layer PNS may be integrally formed without an interface.

The second bank BK2 may be located on the first bank BK1. The second bank BK2 may be located on the first bank BK1 to overlap the first bank BK1. The area of the second bank BK2 may be smaller than the area of the first bank BK1. For example, in plan view, the area of the second bank BK2 may be smaller than the area of the first bank BK1 so that the second bank BK2 is surrounded by the edge of the first bank BK1. An etch rate of the second bank BK2 may be different from an etch rate of the first bank BK1. For example, the etch rate of the second bank BK2 may be higher than the etch rate of the first bank BK1. The second bank BK2 may include a material including silicon nitride (SiNₓ). Alternatively, the second bank BK2 may include a material including a metal. For example, the second bank BK2 may include a material including at least one of titanium (Ti), tantalum (Ta), and molybdenum (Mo).

The third bank BK3 may be located on the second bank BK2. The third bank BK3 may be located on the second bank BK2 to overlap the second bank BK2. The area of the third bank BK3 may be greater than the area of the second bank BK2. For example, in plan view, the area of the third bank BK3 may be greater than the area of the second bank BK2 so that the third bank BK3 surrounds the edge of the second bank BK2. Accordingly, as illustrated in FIG. 9, the third bank BK3 may include a tip TP not overlapping the second bank BK2. An etch rate of the second bank BK2 may be different from an etch rate of the third bank BK3. For example, the etch rate of the second bank BK2 may be higher than the etch rate of the third bank BK3. The third bank BK3 may include a material such as silicon oxide (SiOx).

In cross-section, the separator SPR including the first bank BK1, the second bank BK2, and the third bank BK3 may be smaller at the central portion than at the top and bottom.

The light emitting stack IL may be located on the first electrodes AND, the pixel defining layers PDL, and the separator SPR. For example, the light emitting stack IL may be located on the first bank BK1 and the third bank BK3 of the separator SPR. The light emitting stack IL may be cut on the separator SPR. For example, the light emitting stack IL may be cut between the first bank BK1 and the third bank BK3. In plan view, the light emitting stack IL may be cut along the separator SPR. Therefore, the light emitting stack IL may be divided into a portion in contact with the first electrode AND in each emission area and a portion located on an area excluding the emission area (e.g., on the third bank BK3 of the separator SPR). In other words, the light emitting stack IL may be cut along the separator SPR so that it is separated for each subpixel. Accordingly, lateral leakage current between adjacent subpixels SP1 through SP3 can be minimized. As the lateral leakage current is minimized, a color mixing phenomenon between the adjacent subpixels SP1 through SP3 can be prevented, thereby improving the image quality of the display device 10.

The light emitting stack IL may include a plurality of stack layers stacked sequentially along the third direction DR3. For example, the light emitting stack IL may have a three-tandem structure including a first stack layer, a second stack layer on the first stack layer, and a third stack layer on the second stack layer. Here, the second stack layer may be located between the first stack layer and the third stack layer. However, aspects of the present specification are not limited thereto. For example, the light emitting stack IL may also have a two-tandem structure including two stack layers.

In the three-tandem structure, the first stack layer, the second stack layer, and the third stack layer of the light emitting stack IL may provide light of different colors (or wavelengths). For example, any one of the first stack layer, the second stack layer and the third stack layer may provide light of a first color (e.g., green), another stack layer may provide light of a second color (e.g., red), and the other stack layer may provide light of a third color (e.g., blue).

The first stack layer of the light emitting stack IL may have a structure in which a first hole transport layer, a first organic light emitting layer, and a first electron transport layer are sequentially stacked. The second stack layer of the light emitting stack IL may have a structure in which a second hole transport layer, a second organic light emitting layer, and a second electron transport layer are sequentially stacked. The third stack layer of the light emitting stack IL may have a structure in which a third hole transport layer, a third organic light emitting layer, and a third electron transport layer are sequentially stacked. Here, the first organic light emitting layer, the second organic light emitting layer, and the third organic light emitting layer may provide light of different colors (or wavelengths). For example, any one of the first organic light emitting layer, the second organic light emitting layer and the third organic light emitting layer may provide light of the first color (e.g., green), another organic light emitting layer may provide light of the second color (e.g., red), and the other organic light emitting layer may provide light of the third color (e.g., blue).

A first charge generation layer may be located between the first stack layer and the second stack layer to supply charges to the second stack layer and electrons to the first stack layer. The first charge generation layer may include an n-type charge generation layer that supplies electrons to the first stack layer and a p-type charge generation layer that supplies holes to the second stack layer. The n-type charge generation layer may include a dopant of a metallic material.

A second charge generation layer may be located between the second stack layer and the third stack layer to supply charges to the third stack layer and electrons to the second stack layer. The second charge generation layer may include an n-type charge generation layer that supplies electrons to the second stack layer and a p-type charge generation layer that supplies holes to the third stack layer.

The first stack layer of the light emitting stack IL may be located on the first electrodes AND, the pixel defining layers PDL and the separator SPR. Due to the separator SPR described above, the first stack layer of the light emitting stack IL may be broken between neighboring subpixels SP1 through SP3. The second stack layer of the light emitting stack IL may be located on the first stack layer. Due to the separator SPR described above, the second stack layer IL2 may be broken between the neighboring subpixels SP1 through SP3. The third stack layer of the light emitting stack IL may be located on the second stack layer. The third stack layer of the light emitting stack IL may not be broken by the separator SPR and may cover the second stack layer.

In the three-tandem structure, the separator SPR may be a structure for breaking the first charge generation layer and the second charge generation layer of the display element layer EML between neighboring subpixels SP1 through SP3. In addition, in the two-tandem structure, the separator SPR may be a structure for breaking a charge generation layer located between a lower stack layer and an upper stack layer.

The second electrode CAT may be located on the light emitting stack IL. For example, the second electrode CAT may be located on the third stack layer of the light emitting stack IL. The second electrode CAT may be located on the third stack layer of the light emitting stack IL without being broken by the separator SPR. The second electrode CAT may include a semi-transmissive conductive material such as magnesium (Mg), silver (Ag), or an alloy of magnesium (Mg) and silver (Ag). In this case, the light output efficiency of each of the first through third subpixels SP1 through SP3 may be increased by a microcavity.

The encapsulation layer TFE may be located on the display element layer EML. The encapsulation layer TFE may include one or more inorganic layers TFE1 and TFE2 to prevent the penetration of oxygen or moisture into the display element layer EML. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be located on the second electrode CAT. The first encapsulating inorganic layer TFE1 may be a multilayer in which one or more inorganic layer selected from silicon nitride (SiNₓ), silicon oxynitride (SiON), and silicon oxide (SiOₓ) are alternately stacked. The first encapsulating inorganic layer TFE1 may be formed by a chemical vapor deposition (CVD) process.

The encapsulating organic layer TFE2 may be a monomer. Alternatively, the encapsulating organic layer TFE2 may be an organic layer such as acryl resin, epoxy resin, phenolic resin, polyamide resin, or polyimide resin.

The second encapsulating inorganic layer TFE3 may be located on the encapsulating organic layer TFE2. The second encapsulating inorganic layer TFE3 may be a multilayer in which one or more inorganic layers selected from silicon nitride (SiNₓ), silicon oxynitride (SiON), and silicon oxide (SiOₓ) are alternately stacked. The second encapsulating inorganic layer TFE3 may be formed by a chemical vapor deposition (CVD) process. As another example, the second encapsulating inorganic layer TFE3 may be formed of titanium oxide (TiOₓ) or aluminum oxide (AlOx: e.g., A₂O₃). At this time, the second encapsulating inorganic layer TFE3 may be formed by an atomic layer deposition (ALD) method. In this case, the second encapsulating inorganic layer TFE3 may be the equal to or smaller than 100 nm.

An organic layer APL may be a layer for increasing the interfacial adhesion between the encapsulation layer TFE and the optical layer OPL. The organic layer APL may be an organic layer such as acryl resin, epoxy resin, phenolic resin, polyamide resin, or polyimide resin.

The optical layer OPL includes a plurality of color filters CF1 through CF3, a plurality of lenses LNS, and a filling layer FIL. The color filters CF1 through CF3 may include first through third color filters CF1 through CF3. The first through third color filters CF1 through CF3 may be located on an adhesive layer ADL.

The first color filter CF1 may overlap the first emission area EA1 of the first subpixel SP1. The first color filter CF1 may transmit light of the first color (e.g., light in the red wavelength band). Therefore, the first color filter CF1 may transmit the light of the first color among the light emitted from the light emitting stack IL of the first emission area EA1.

The second color filter CF2 may overlap the second emission area EA2 of the second subpixel SP2. The second color filter CF2 may transmit light of the second color (e.g., light in the green wavelength band). Therefore, the second color filter CF2 may transmit the light of the second color among the light emitted from the light emitting stack IL of the second emission area EA2.

The third color filter CF3 may overlap the third emission area EA3 of the third subpixel SP3. The third color filter CF3 may transmit light of the third color (e.g., light in the blue wavelength band). Therefore, the third color filter CF3 may transmit the light of the third color among the light emitted from the light emitting stack IL of the third emission area EA3.

The lenses LNS may be located on the first color filter CF1, the second color filter CF2, and the third color filter CF3, respectively. Each of the lenses LNS may be a structure for increasing the proportion of light directed to the front of the display device 10. Each of the lenses LNS may have an upwardly convex cross-sectional shape, but aspects of the present specification are not limited thereto.

The filling layer FIL may be located on the lenses LNS. The filling layer FIL may have a predetermined refractive index so that light can travel in the third direction DR3 at an interface between the lenses LNS and the filling layer FIL. In addition, the filling layer FIL may be a planarization layer. The filling layer FIL may be an organic layer such as acryl resin, epoxy resin, phenolic resin, polyamide resin, or polyimide resin.

The cover layer CVL may be located on the filling layer FIL. The cover layer CVL may be a glass substrate or polymer resin such as resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is polymer resin such as resin, it may be directly applied on the filling layer FIL.

The polarizing plate POL may be located on a surface of the cover layer CVL. The polarizing plate POL may be a structure for preventing visibility reduction due to the reflection of external light. The polarizing plate POL may include a linear polarizing plate and a phase retardation film. For example, the phase retardation film may be a quarter-wave plate (λ/4 plate), but aspects of the present specification are not limited thereto. If visibility reduction due to the reflection of external light is sufficiently improved by the first through third color filters CF1 through CF3, the polarizing plate POL may be omitted.

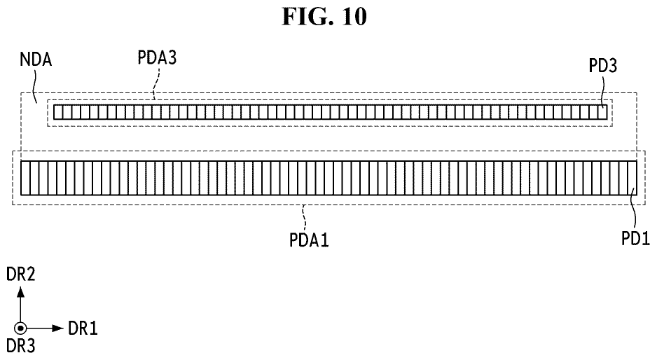

FIG. 10 is an enlarged view of the periphery of the first pad PDA1 of FIG. 4.

As illustrated in FIG. 10, the first pad portion PDA1 may include a plurality of first pads PD1 arranged along the first direction DR1. As described above, the first pads PD1 may be connected to bumps (or pads) of the circuit board 300 through a conductive adhesive member.

A third pad portion PDA3 may be located on the upper side of the first pad portion PDA1, for example, between the first pad portion PDA1 and the data driver 700. The third pad portion PDA3 may include a plurality of third pads PD3 along the first direction DR1.

The third pads PD3 may be connected to the bumps (or pads) of the data driver 700 through a conductive adhesive member. For example, the data driver 700 may be manufactured in a form of a chip including an integrated circuit, and the bumps of such data driver 700 of a chip form may be connected to the third pads PD3. The data driver 700 may be connected to the first pads PD1 and the pixels PX of the display panel 100 through the third pads PD3.

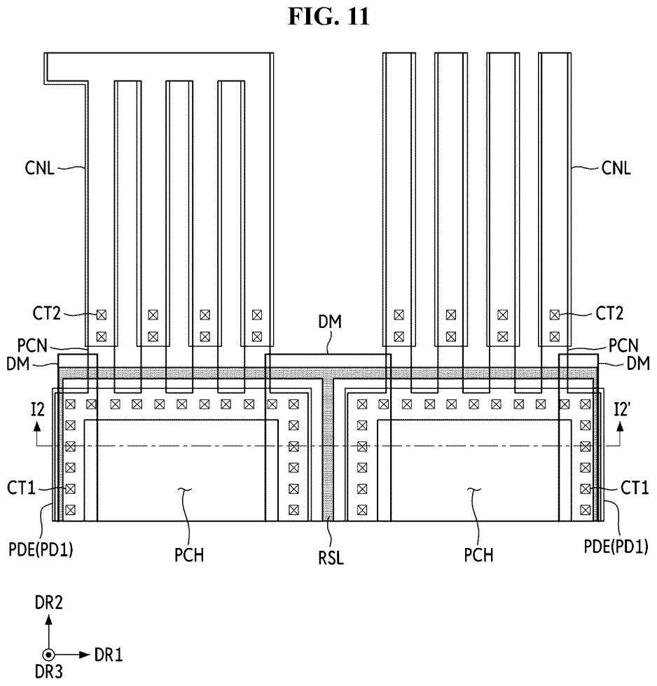

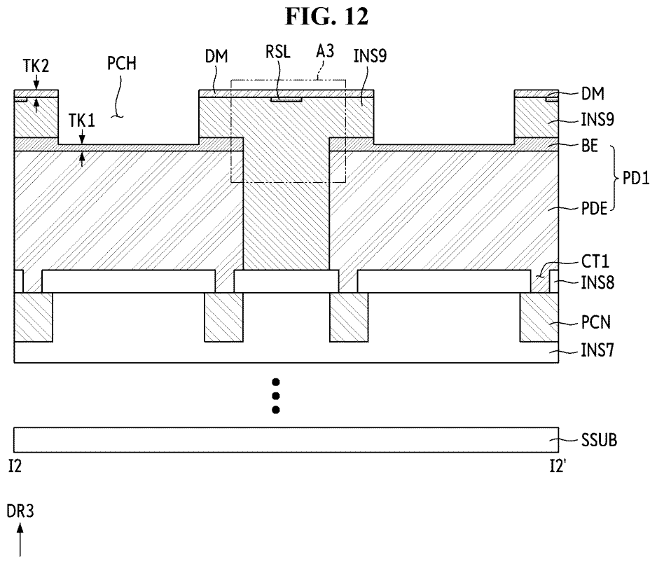

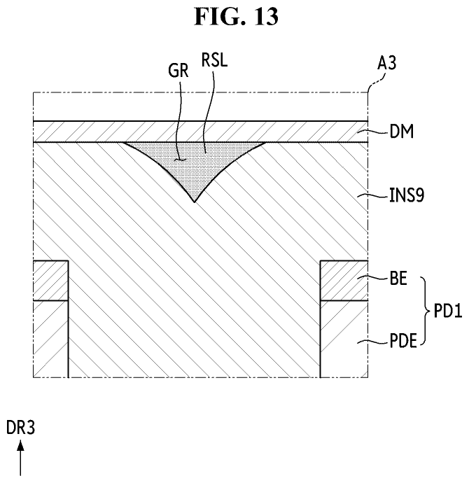

FIG. 11 is a plan view of two adjacent first pads PD1 of FIG. 10, FIG. 12 is a cross-sectional view of a display panel 100 taken along line I2-I2′ of FIG. 11, and FIG. 13 is an enlarged view of area A3 of FIG. 12.

As illustrated in FIG. 12, the first pad PD1 may be located on the eighth insulating layer INS8.

The ninth insulating layer INS9 may be disposed on the first pad PD1. The first pad PD1 may be exposed to the outside through a pad contact hole PCH penetrating the ninth insulating layer INS9. For example, the first pad PD1 may overlap the pad contact hole PCH penetrating the ninth insulating layer INS9.

The first pad PD1 may be connected to a pad connection electrode PCN on the seventh insulating layer INS7. For example, the first pad PD1 may be connected to the pad connection electrode PCN through a first contact hole CT1 penetrating the eighth insulating layer INS8. As illustrated in FIG. 11, the pad connection electrode PCN may be connected to a pad line CNL through a second contact hole CT2. The first pad PD1 may be connected to the pad line CNL through the pad connection electrode PCN. The pad line CNL may be connected to a third pad PD3.

As illustrated in FIG. 12, the first pad PD1 may include a pad electrode PDE and a buffer electrode BE.

The pad electrode PDE may be located on the eighth insulating layer INS8. The pad electrode PDE may be connected to the pad connection electrode PCN through a first contact hole of the eighth insulating layer INS8. The pad electrode PDE may be formed of a material including aluminum.

The buffer electrode BE may be located on the pad electrode PDE. The buffer electrode BE may be connected to the pad electrode PDE. For example, the buffer electrode BE may contact (or directly contact) the upper surface of the pad electrode PDE. A thickness TK1 of the central portion of the buffer electrode BE may be smaller than a thickness of the edge of the buffer electrode BE. For example, the buffer electrode BE may have a smaller thickness TK1 in an area not overlapping the ninth insulating layer INS9 than in an area overlapping the ninth insulating layer INS9. The thickness of TK1 of the central portion of the buffer electrode BE may be 600 Å. The buffer electrode BE may include a material including titanium nitride (TiN). A contact resistance between the bump of the circuit board 300 and the pad electrode PDE may be reduced by the buffer electrode BE.

The ninth insulating layer INS9 may be located on the buffer electrode BE. The ninth insulating layer INS9 may be located on the edge of the buffer electrode BE. The ninth insulating layer INS9 may have a pad contact hole PCH exposing the first pad PD1, for example, the buffer electrode BE of the first pad PD1.

A residual layer RSL may be located on the ninth insulating layer INS9. The residual layer RSL may be formed of the same material as, for example, the ninth via electrode VA9. The residual layer RSL may remain on the ninth insulating layer INS9 in a process of forming the ninth via electrode VA9. For example, as illustrated in FIG. 13, the ninth insulating layer INS9 may have a groove GR recessed toward the semiconductor substrate SSUB in an area overlapping with gaps between the adjacent first pads PD1, and the residual layer RSL may be located in the groove GR of the ninth insulating layer INS9. Since the pad electrode PDE is not located between the adjacent first pads PD1, the ninth insulating layer INS9 may not be supported by the pad electrode PDE between the adjacent first pads PD1. Due to this, the ninth insulating layer INS9 may be recessed toward the semiconductor substrate SSUB between the adjacent first pads PD1, and at this time, the residual layer RSL may be located in the groove GR which is formed as the ninth insulating layer INS9 is recessed. Here, as the material (e.g., tungsten) of the ninth via electrode VA9 is formed on the ninth insulating layer INS9 and then the tungsten of the ninth via electrode VA9 is removed through a chemical mechanical polishing, the ninth via electrode VA9 may be formed inside the via hole of the ninth insulating layer INS9, and at this time, the residual layer RSL may remain without the tungsten inside the groove GR being removed due to the groove GR of the ninth insulating layer INS9.

A dummy layer DM may be located on the ninth insulating layer INS9 and the residual layer RSL. The dummy layer DM may cover the residual layer RSL so that the residual layer RSL is not exposed to the outside. For example, the dummy layer DM may prevent short circuit between the adjacent first pads PD1 by the residual layer RSL. In a plan view as illustrated in FIG. 11, the area of the dummy layer DM may be greater than the area of the residual layer RSL.

A thickness TK2 of the dummy layer DM may be greater than the thickness TK1 of the buffer electrode BE. For example, the thickness TK2 of the dummy layer DM may be 1200 Å.

The dummy layer DM may include, for example, an insulating material. According to an aspect, the dummy layer DM may include a material including aluminum oxide (Al₂O₃). The dummy layer DM may be formed on the ninth insulating layer INS9 and the residual layer RSL through an atomic layer deposition method. According to an aspect, the dummy layer DM may be formed of the same material as the encapsulation layer TFE. For example, the dummy layer DM may be formed of the same material as the second encapsulating inorganic layer TFE3. According to an aspect, the dummy layer DM and the second encapsulating inorganic layer TFE3 may include a material including aluminum oxide. At this time, the dummy layer DM and the second encapsulating inorganic layer TFE3 may be formed at the same time through the same process.

In a plan view as illustrated in FIG. 11, the dummy layer DM may surround the edge of the residual layer RSL to overlap the entire residual layer RSL. According to another aspect, the dummy layer DM may be located on the entire display panel 100 excluding the pad contact holes PCH to overlap the entire residual layer RSL. For example, the dummy layer DM may be located on the entire area of the display panel 100 to overlap the entire display panel 100 of FIG. 4. In other words, the dummy layer DM may be located on the entire surface of the semiconductor substrate SSUB excluding the pad contact hole PCH. In this case, the dummy layer DM may be integrally formed with the second encapsulating inorganic layer TFE3.

In a cross-sectional view as illustrated in FIG. 13, the residual layer RSL may be located between the ninth insulating layer INS9 and the dummy layer DM. For example, the residual layer RSL may be located between the groove GR of the ninth insulating layer INS9 and the dummy layer DM.

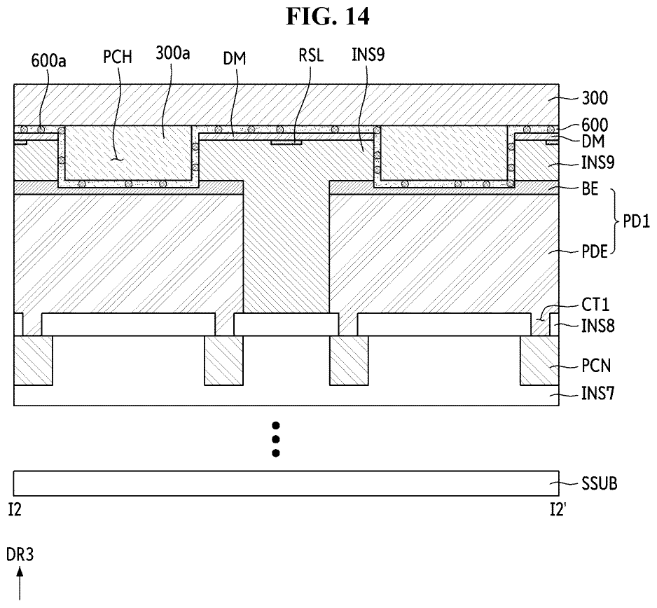

FIG. 14 is a diagram for explaining a connection between the display panel 100 and the circuit board 300 of FIG. 12.

As illustrated in FIG. 14, the first pad PD1 of the display panel 100 and a bump 300a of the circuit board 300 may be electrically connected to each other through a conductive adhesive member 600.

The conductive adhesive member 600 may be located between the first pad portion PDA1 of the display panel 100 and the circuit board 300. For example, the conductive adhesive member 600 may be located on the first pad portion PDA1 of the display panel 100. The conductive adhesive member 600 may include a plurality of conductive members 600a. The first pads PD1 (e.g., the buffer electrode BE) and the bump 300a may be electrically connected to each other through conductive members 600a.

The dummy layer DM may be located between the ninth insulating layer INS9 of the first pad portion PDA1 and the conductive adhesive member 600. For example, in the first pad portion PDA1, the dummy layer DM may be located between the upper surface of the ninth insulating layer INS9 and the conductive adhesive member 600.

As the dummy layer DM described above is located on the residual layer RSL and the ninth insulating layer INS9 to cover the residual layer RSL, a contact between the residual layer RSL and the conductive member 600a may be prevented. When there is no dummy layer DM, the residual layer RSL and the conductive member 600a may be in contact with each other. In this case, the plurality of conductive members 600a may be connected to the adjacent first pads PD1 (or adjacent bumps) through the residual layer RSL, and a short circuit issue in which the adjacent first pads PD1 are electrically connected to each other may occur. When the dummy layer DM covers the residual layer RSL, the residual layer RSL and the conductive member 600a of the conductive adhesive member 600 do not contact each other, and short circuit between the adjacent first pads PD1 may be prevented.

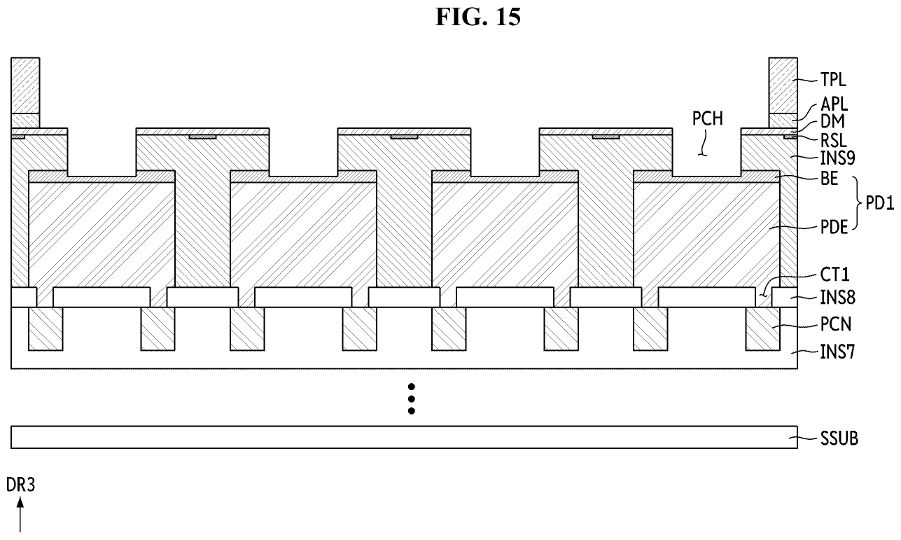

FIG. 15 is a cross-sectional view of a display panel 100 including four adjacent first pads PD1.

As illustrated in FIG. 15, the residual layer RSL may be located between the adjacent first pads PD1, and the dummy layer DM may be located on the ninth insulating layer INS9 to cover each residual layer RSL. For example, the dummy layer DM may cover the upper surface of each residual layer RSL and the upper surface of the ninth insulating layer INS9.

In addition, when the cross-sectional view illustrated in FIG. 15 includes both edges of the first pad portion PDA1, an organic layer APL and a high refractive index organic layer TPL may be located on both edges of the first pad portion PDA1. For example, at both edges of the first pad portion PDA1, an organic layer APL may be located on the dummy layer DM, and the high refractive index organic layer TPL may be located on the organic layer APL. Here, the refractive index organic layer TPL may be formed of the same material as lens LNS.

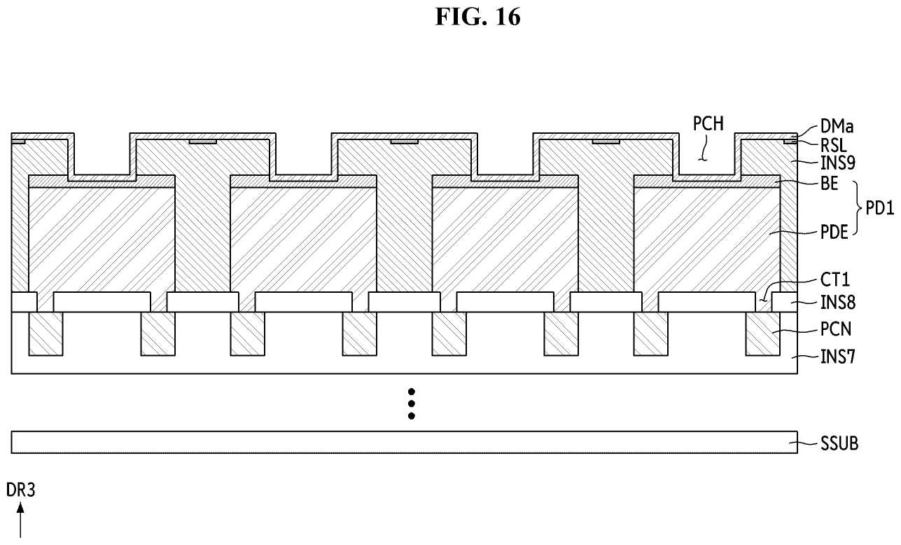

FIGS. 16, 17, 18, 19, and 20 are process cross-sectional views illustrating a method of fabricating a display device according to an aspect. For example, FIGS. 16 to 20 may be process cross-sectional views for explaining a method of fabricating a display device of FIG. 15 described above.

First, as illustrated in FIG. 16, a seventh insulating layer INS7 may be formed on a semiconductor substrate SSUB, and a pad connection electrode PCN may be formed inside a via hole of the seventh insulating layer INS7. Subsequently, after forming an eighth insulating layer INS8 on the pad connection electrode PCN, a first contact hole CT1 exposing the pad connection electrode PCN may be formed by penetrating the eighth insulating layer INS8. Next, a first pad PD1 connected to the pad connection electrode PCN through the first contact hole CT1 may be formed on the eighth insulating layer INS8. For example, the pad electrode PDE and a buffer electrode BE may be formed together through one mask process. Then, after forming a ninth insulating layer INS9 on the entire surface of the semiconductor substrate SSUB including the first pad PD1 and the eighth insulating layer INS8, a via hole exposing the eighth conductive layer ML8 may be formed by penetrating the ninth insulating layer INS9 (see FIG. 7). Next, a material (e.g., tungsten) of the ninth via electrode VA9 may be formed inside the via hole of the ninth insulating layer INS9 and on the ninth insulating layer INS9. Then, the material of the ninth via electrode VA9 on the ninth insulating layer INS9 may be removed by patterning the material of the ninth via electrode VA9 through a chemical mechanical polishing. Accordingly, the ninth via electrode VA9 may be formed inside the via hole of the ninth insulating layer INS9. At this time, as described above, a residual layer RSL formed of the same material as the ninth via electrode VA9 may be formed on the ninth insulating layer INS9 of the first pad portion PDA1. For example, the residual layer RSL may be formed in a groove GR on the ninth insulating layer INS9 between the adjacent first pads PD1. Subsequently, a pad contact hole PCH exposing the buffer electrode BE of the first pad PD1 may be formed by penetrating the ninth insulating layer INS9. Next, an intermediate layer DMa may be formed on the ninth insulating layer INS9, the buffer electrode BE, the inner wall of the pad contact hole PCH, and on the residual layer RSL. The intermediate layer DMa may be formed on the entire surface of the semiconductor substrate SSUB including the ninth insulating layer INS9, the buffer electrode BE, the inner wall of the pad contact hole PCH, and the residual layer RSL, for example, by an atomic layer deposition method. The intermediate layer DMa may include a material including aluminum oxide (Al₂O₃). At this time, the intermediate layer DMa may be formed even on the encapsulating organic layer TFE2.

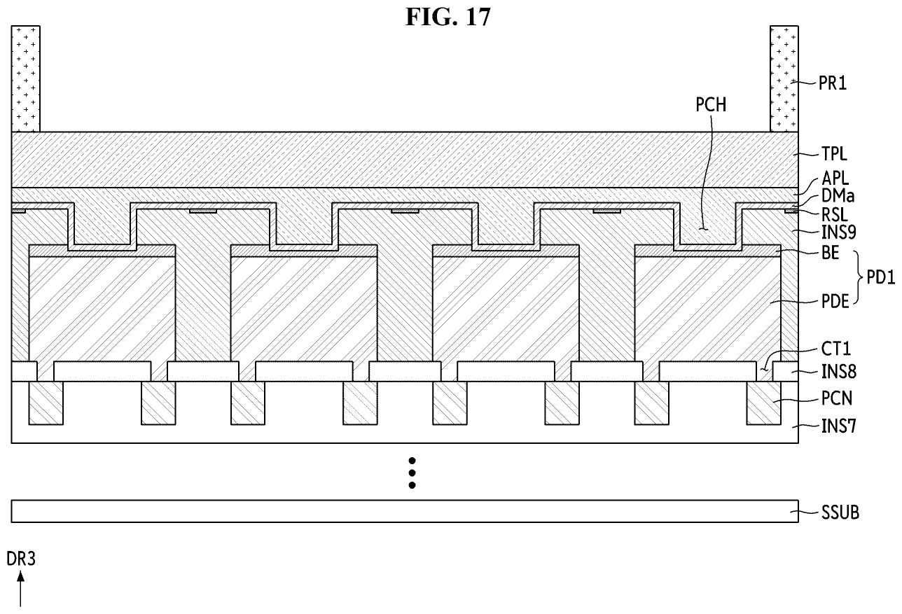

Subsequently, as illustrated in FIG. 17, an organic layer APL may be formed on the intermediate layer DMa, a high refractive index organic layer TPL may be formed on the organic layer APL, and a first photoresist pattern PR1 may be formed on the high refractive index organic layer TPL. Here, the first photoresist pattern PR1 may be located on the high refractive index organic layer TPL to expose the first pad portion PDA1 (e, g., the first pads PD1 of the first pad portion PDA1). Here, the high refractive index organic layer TPL may be formed of the same material as lens LNS of the display area DAA.

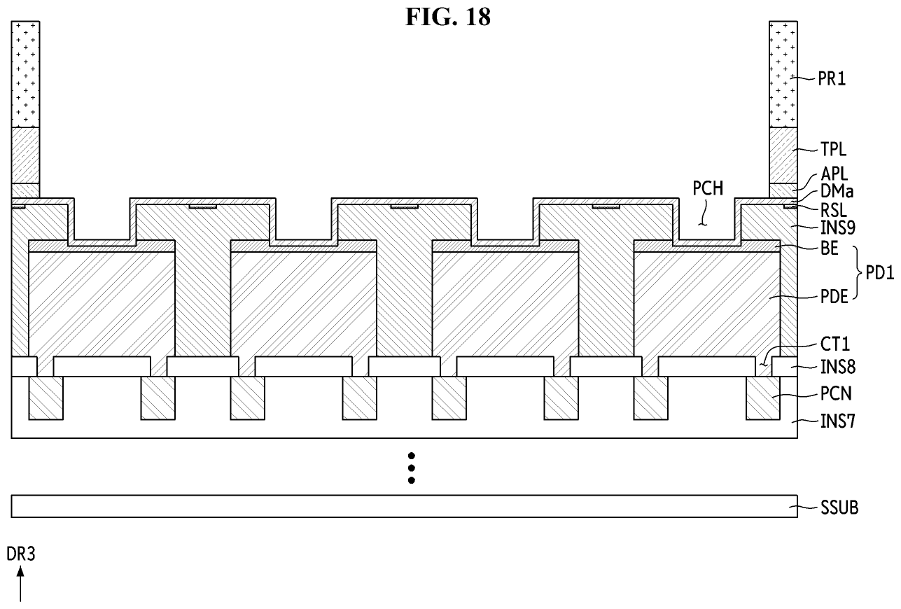

Next, as illustrated in FIG. 18, the high refractive index organic layer TPL and the organic layer APL may be patterned as the high refractive index organic layer TPL and the organic layer APL are removed using the first photoresist pattern PR1 as a mask. Here, the high refractive index organic layer TPL and the organic layer APL may be removed by a dry etching using oxygen (O₂). Accordingly, the intermediate layer DMa of the first pad portion PDA1 may be exposed. In the patterning process of FIG. 18, the intermediate layer DMa may function as an etch stopper.

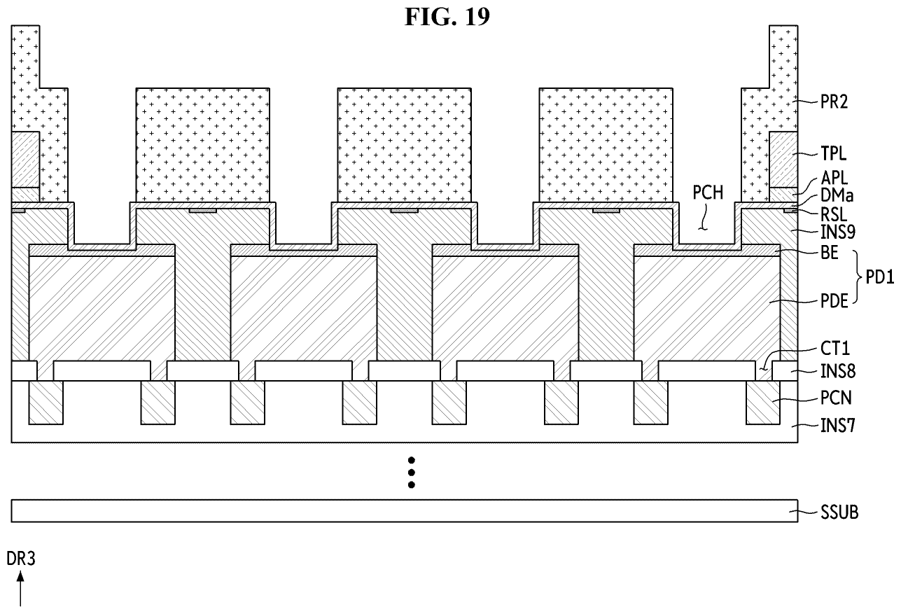

Next, after removing the first photoresist pattern PR1, a second photoresist pattern PR2 may be formed on the intermediate layer DMa and the high refractive index organic layer TPL as illustrated in FIG. 19. Here, the second photoresist pattern PR2 may be located on the intermediate layer DMa and the high refractive index organic layer TPL.

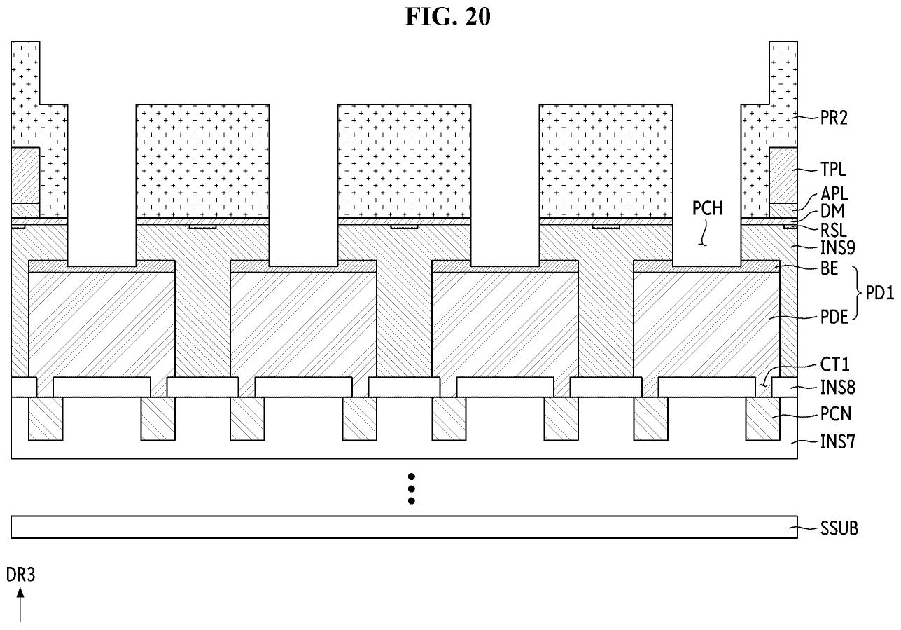

Subsequently, as illustrated in FIG. 20, a dummy layer DM may be formed by removing the intermediate layer DMa using the second photoresist pattern PR2 as a mask. For example, the dummy layer DM may be formed on the ninth insulating layer INS9 by patterning the intermediate layer DMa so that the intermediate layer DMa on the buffer electrode BE and the inner wall of the pad contact hole PCH is removed. Here, the intermediate layer DMa may be removed by a dry etching using carbon tetrafluoride (CF₄).

The dummy layer DM may cover the residual layer RSL on the ninth insulating layer INS9. The residual layer RSL may not be exposed to the outside by the dummy layer DM. In a processing process in which the intermediate layer DMa is removed using the second photoresist pattern PR2, a part of the central portion of the buffer electrode BE overlapping the pad contact hole PCH may be removed. Accordingly, the thickness TK1 of the central portion of the buffer electrode BE may be smaller than the thickness of the edge of the buffer electrode BE. When the intermediate layer DMa is being patterned, the dummy layer DM and the second encapsulating inorganic layer TFE3 described above may be formed together.

Thereafter, as illustrated in FIG. 15, the second photoresist pattern PR2 may be removed

The display device 10 according to the aspect can be applied to various electronic devices. An electronic device according to an aspect includes the above-described display device 10 and may further include modules or devices having other additional functions, in addition to the display device 10.

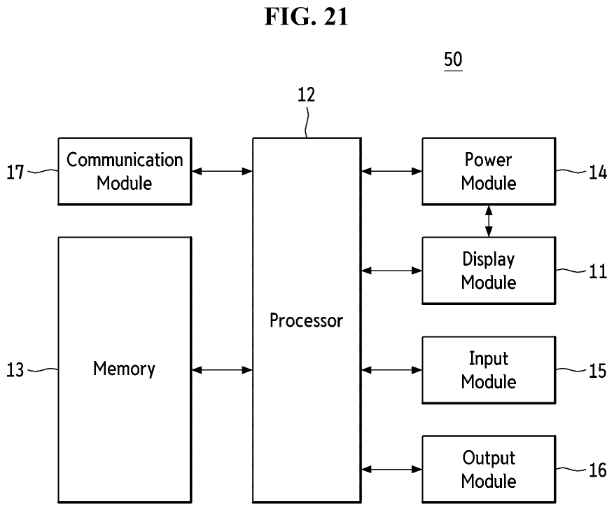

FIG. 21 is a block diagram of an electronic device according to an aspect. Referring to FIG. 21, an electronic device 50 according to the aspect may include a display module 11, a processor 12, a memory 13, and a power module 14. The electronic device 50 may further include an input module 15, an output module 16 (e.g. a non-image output module 16), and/or a communication module 17.

The electronic device 50 may output various information in the form of images through the display module 11. When the processor 12 executes an application stored in the memory 13, image information provided by the application may be provided to a user through the display module 11. The power module 14 may include a power supply module such as a power adapter or a battery device and a power conversion module which generates power necessary for the operation of the electronic device 50 by converting power supplied by the power supply module. The input module 15 may provide input information to the processor 12 and/or the display module 11. The non-image output module 16 may receive non-image information, such as sound, haptic and light, from the processor 12 and provide the information to a user. The communication module 17 is a module that is responsible for transmitting and receiving information between the electronic device 50 and an external device and may include a receiving unit and a transmitting unit.

At least one of the elements of the electronic device 50 described above may be included in a display device according to the aspects described above. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 50.

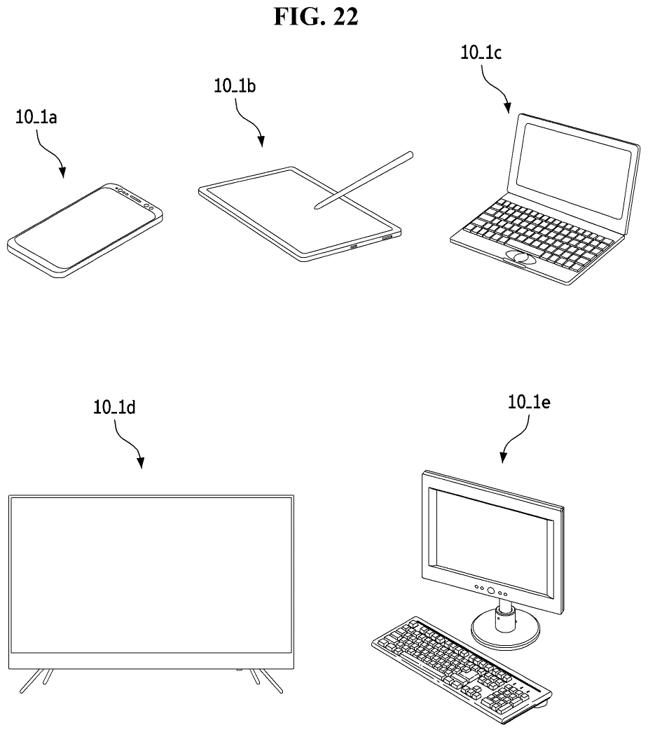

FIGS. 22, 23, and 24 are schematic diagrams of electronic devices according to various aspects. FIGS. 22 through 24 illustrate examples of various electronic devices to which a display device 10 according to aspects is applied.

FIG. 22 illustrates a smartphone 10_1a, a tablet PC 10_1b, a laptop 10_1c, a television 10_1d, and a desk monitor 10_1e as examples of electronic devices.

The smartphone 10_1a may include an input module such as a touch sensor and a communication module in addition to a display module 11. The smartphone 10_1a may process information received through the communication module or other input modules and display the information through a display module of a display device.

Like the smartphone 10_1a, the tablet PC 10_1b, the laptop 10_1c, the television 10_1d, and the desk monitor 10_1e may also include a display module and an input module and may further include a communication module in some cases.

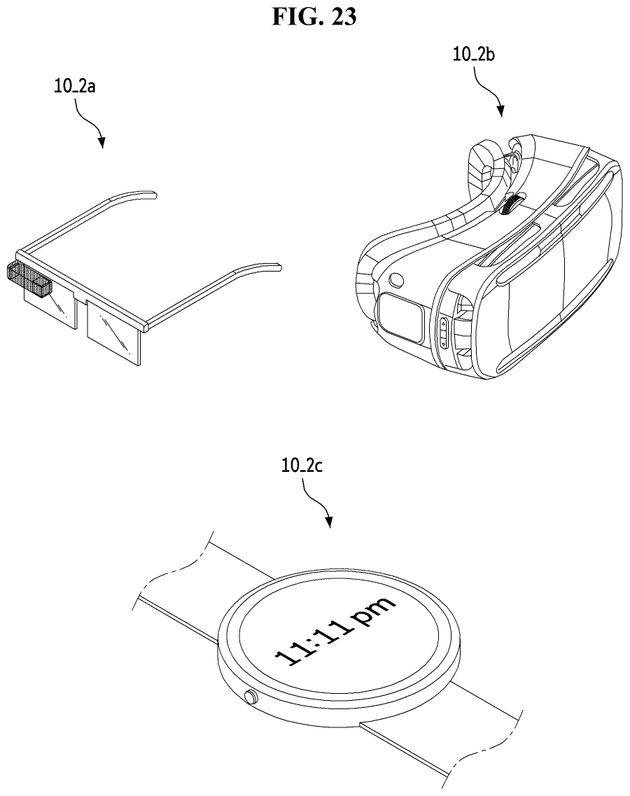

FIG. 23 illustrates a case where an electronic device including a display module is applied to a wearable electronic device. The wearable electronic device may be smart glasses 10_2a, a head mounted display 10_2b, a smart watch 10_2c, or the like.

The smart glasses 10_2a and the head mounted display 10_2b may include a display module which outputs a display image and a reflector which provides the output display screen to a user's eyes by reflecting the output display screen. Accordingly, a screen of virtual reality or augmented reality can be provided to the user.

The smart watch 10_2c may include a biometric sensor as an input device and may provide biometric information recognized by the biometric sensor to a user through a display module.

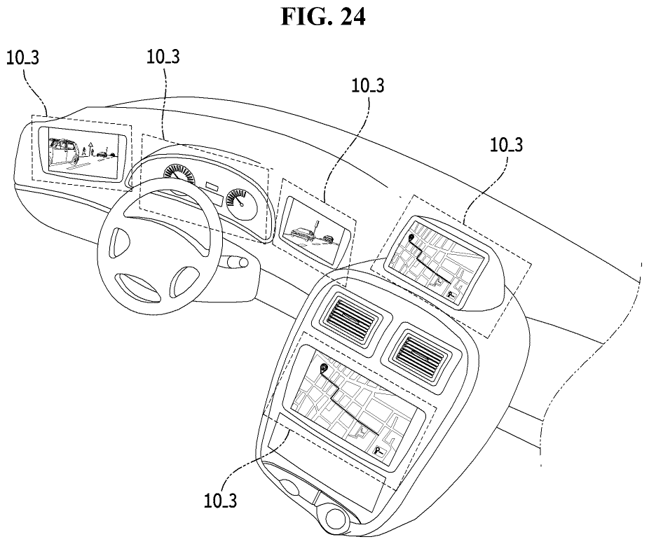

FIG. 24 illustrates a case where an electronic device including a display module is applied to a vehicle. For example, an electronic device 10_3 may be applied to an instrument panel, center fascia, etc. of a vehicle, may be applied to a center information display (CID) located on a dashboard of the vehicle, or may be applied to a room mirror display replacing a side mirror.

In concluding the detailed description, those skilled in the art will appreciate that many variations and modifications can be made to the preferred aspects without substantially departing from the principles of the present disclosure. Therefore, the disclosed preferred aspects of the disclosure are used in a generic and descriptive sense only and not for purposes of limitation.

What is claimed is:

1. A display device comprising:
a substrate having a display area and a non-display area;
an insulating layer located in the display area and the non-display area;
a connection electrode located in the display area of the substrate, the connection electrode on the insulating layer;
a reflective electrode on the connection electrode;
a capping layer on the reflective electrode;
a first electrode on the capping layer;
a pixel defining layer on the first electrode and defining an emission area exposing the first electrode;
a light emitting stack on the first electrode and on the pixel defining layer;
a second electrode on the light emitting stack;
two pads located in a pad portion of the non-display area of the substrate, the insulating layer on the pads, for each pad, the insulating layer having a pad contact hole exposing the pad;
a residual layer on the insulating layer, the residual layer comprising a conductive material, the residual layer located between the two pads; and
a dummy layer on the residual layer, the dummy layer comprising an insulating material.

2. The display device of claim 1,
wherein the dummy layer covers the residual layer.

3. The display device of claim 1,
further comprising a conductive adhesive member located in the pad portion of the non-display area of the substrate, the conductive adhesive member on the two pads.

4. The display device of claim 3,
wherein the dummy layer is located between the insulating layer located in the pad portion and the conductive adhesive member.

5. The display device of claim 1,
wherein, in plan view, an area of the dummy layer is greater than an area of the residual layer.

6. The display device of claim 1,
wherein, in plan view, the dummy layer surrounds an edge of the residual layer.

7. The display device of claim 1,
wherein the dummy layer is located on an entire surface of the substrate excluding the pad contact hole.

8. The display device of claim 1,
further comprising an encapsulation layer on the second electrode.

9. The display device of claim 8,
wherein the dummy layer includes the same material as the encapsulation layer.

10. The display device of claim 9,
wherein the dummy layer is integrally formed with the encapsulation layer.

11. The display device of claim 1,
wherein the dummy layer comprises aluminum oxide.

12. The display device of claim 1,
wherein the residual layer is between the insulating layer and the dummy layer.

13. The display device of claim 1,
wherein the insulating layer has a groove recessed toward the substrate, the groove located between the two pads.

14. The display device of claim 13,
wherein the residual layer is located inside the groove of the insulating layer.

15. The display device of claim 14,
wherein the residual layer is located between the groove of the insulating layer and the dummy layer.

16. The display device of claim 1,
wherein the residual layer comprises the same material as a ninth via electrode located in the insulating layer, the ninth via electrode connected to the connection electrode.

17. The display device of claim 1,
wherein the residual layer comprises tungsten.

18. An electronic device comprising a display device providing a display screen,
wherein the display device comprises:
a substrate having a display area and a non-display area;
an insulating layer located in the display area and the non-display area;
a connection electrode located in the display area of the substrate, the connection electrode on the insulating layer;
a reflective electrode on the connection electrode;
a capping layer on the reflective electrode;
a first electrode on the capping layer;
a pixel defining layer on the first electrode and defining an emission area exposing the first electrode;
a light emitting stack on the first electrode and on the pixel defining layer;
a second electrode on the light emitting stack;
two pads located in a pad portion of the non-display area of the substrate, the insulating layer on the pads, for each pad, the insulating layer having a pad contact hole exposing the pad;
a residual layer on the insulating layer, the residual layer comprising a conductive material, the residual layer located between the two pads; and
a dummy layer located on the residual layer, the dummy layer comprising an insulating material.

19. The electronic device of claim 18,
wherein the electronic device includes a smart phone, a tablet, a laptop, a television, a desk monitor, smart glasses, a smart watch, a head-mounted display or a vehicle.

20. A method for fabricating a display device, the method comprising:
forming a first insulating layer on a semiconductor substrate having a display area and a non-display area;
forming a pad connection electrode inside a via hole of the first insulating layer, the pad connection electrode located in the non-display area;
forming a second insulating layer on the pad connection electrode;
forming a first contact hole that exposes the pad connection electrode by penetrating the second insulating layer;
forming a pad connected to the pad connection electrode through the first contact hole on the second insulating layer;
forming a third insulating layer on the entire surface of the substrate including the pad and the second insulating layer;
forming a via hole of the third insulating layer, the via hole located in the display area;
forming a via electrode inside the via hole of the third insulating layer and simultaneously forming a residual layer on the third insulating layer in the non-display area;
forming a pad contact hole that exposes the pad by penetrating the third insulating layer;
forming an intermediate layer on the third insulating layer, the pad, an inner wall of the pad contact hole and the residual layer;
forming an organic layer on the intermediate layer;
forming a high refractive index organic layer on the organic layer;
forming a first photoresist pattern on the high refractive index organic layer;
etching the high refractive index organic layer and the organic layer using the first photoresist pattern as a mask to expose the intermediate layer on the pad;
removing the first photoresist pattern;
forming a second photoresist pattern on the intermediate layer and the high refractive index organic layer to expose the pad contact hole; and
using the second photoresist pattern as a mask, removing a portion of intermediate layer over the pad, but not removing a portion of the intermediate layer over the residual layer.
